(19) United States
(12) Patent Application Publication
(10) Pub. No.: US 2024/0206072 A1
(43) Pub. Date: Jun. 20, 2024

(54) LIGHT-EMITTING DIODE ARRAY WITH PRECISE POSITION ASSEMBLY FOR AUTOMOTIVE HEADLIGHT APPLICATIONS

(71) Applicant: LUMILEDS LLC, San Jose, CA (US)

(72) Inventors: Say Chun OOI, Penang (MY); Chee Ming THOE, Penang (MY); Axel MEHNERT, Santa Clara, CA (US)

(73) Assignee: LUMILEDS LLC, San Jose, CA (US)

(21) Appl. No.: 18/514,521

(22) Filed: Nov. 20, 2023

Related U.S. Application Data
(60) Provisional application No. 63/432,549, filed on Dec. 14, 2022.

(51) Int. Cl. H05K 1/18; H05K 3/30; H05K 3/34

(52) U.S. Cl. CPC H05K 1/181; H05K 3/303; H05K 3/3452; H05K 2201/10106; H05K 2203/048; H05K 2203/049

(57) ABSTRACT

A method for enabling self-aligning light-emitting diodes is provided. The method includes printing a die architecture including solders having a bond line thickness according to a printed circuit board design and placing light-emitting diodes in corresponding placement positions onto the solders. The method includes implementing a reflow process that includes a self-alignment effect for the light-emitting diodes. The self-alignment effect comprises creating surface tension forces while the solders are molten that pull or hold the light-emitting diodes to or at final positions.

### CROSS-REFERENCE TO RELATED APPLICATIONS

This application claims the benefit of provisional U.S. Application No. 63/432,549, filed on Dec. 14, 2022, the contents of which are hereby incorporated by reference in their entirety.

Surface mount technology (“SMT”) components including light-emitting diodes (“LEDs”) can move from an original position after pick and place during a reflow process. This movement of the SMT components (e.g., LEDs) can be random, which may lead to final positions that are not adequate for requirements of adaptive driving beam (“ADB”) headlight with projection optics. Further, these inadequate final positions create an irregular beam pattern on a street in front of a car that is not appreciated by a driver of the car and is a safety risk.

### SUMMARY

According to one or more embodiments, a method for enabling self-aligning light-emitting diodes is provided. The method includes printing a die architecture comprising one or more solders having a bond line thickness according to a printed circuit board design and placing one or more light-emitting diodes in corresponding placement positions onto the one or more solders. The method includes implementing a reflow process that includes a self-alignment effect for the one or more light-emitting diodes. The self-alignment effect comprises creating surface tension forces while the one or more solders are molten that pull or hold the one or more light-emitting diodes to or at final positions.

### BRIEF DESCRIPTION OF THE DRAWINGS

A more detailed understanding can be had from the following description, given by way of example in conjunction with the accompanying drawings wherein:

FIG. 1 shows a method for enabling self-aligning LEDs according to one or more embodiments;

FIG. 2 shows an exemplary process flow for enabling self-aligning LEDs according to one or more embodiments;

FIG. 3 shows an exemplary process flow for enabling self-aligning LEDs according to one or more embodiments;

FIG. 4 shows a set of comparative examples of solder footprints and LED arrangements according one or more embodiments;

FIG. 5 shows a set of comparative graphical examples according one or more embodiments;

FIG. 6 shows a method for enabling self-aligning LEDs according to one or more embodiments;

FIG. 7 is a diagram of an example vehicle headlamp system; and

FIG. 8 is a diagram of another example vehicle headlamp system.

### DETAILED DESCRIPTION

According to one or more embodiments, described herein is a method that may create a footprint on a printed circuit board (PCB) or other substrate that may assist LEDs find optimal positions during solder reflow. The method, by way of example, targets controlling a movement of the LEDs during a liquidous state of a solder during a reflow process. Further, the method may control the movement of the LEDs by building a die architecture according to a PCB design having a solder bond line thickness (BLT) that causes the LEDs to self-align during the reflow process (e.g., the LEDs move to intended positions independent from corresponding placement locations). The method herein may therefore provide the technical effect, advantages, and benefits of a high placement accuracy of the LEDs, such as a placement accuracy h that is less than or equal to 50 micrometers (μm) spacing gap between the LEDs. The method may thereby provide LED arrays, with the high placement accuracy, in a matrix lighting device suitable for a variety of lighting applications, such as automotive headlight applications where light emitted by the LEDs gets projected as low or high beams.

Examples of different light illumination systems and/or LED implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

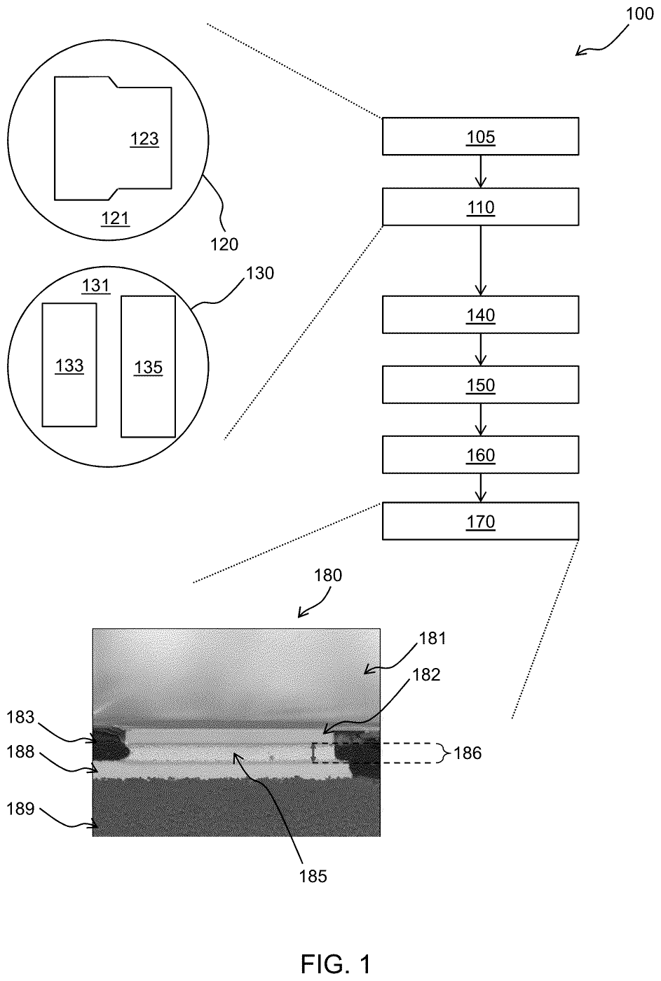

FIG. 1 shows a method 100 for enabling self-aligning LEDs according to one or more embodiments. The method 100 may be implemented by electronics manufacturing equipment, including but not limited to a reflow oven, die architecture or PCB assembly equipment, SMT assembly line equipment, SMT stencil printers, and pick and place machines. The method 100 may begin at block 105, where a PCB design having to a solder BLT that enables self-aligning LEDs (i.e., controls movement of the LEDs) may be generated. The PCB design can be generated in computer design software based on inputs received from a user and stored as a file for execution by the electronics manufacturing equipment.

According to one or more embodiments, the PCB design may be a schematic detailing dimensions of elements and layers, including the solder BLT, of a desired die architecture for receiving the LED array. The PCB design may generally include a PCB, as a carrier, that supports a wiring layer (e.g., a copper layer) including electrical traces. The wiring layer may support a solder mask layer. The LED array can include uniform set of LEDS or any combination and numbering of different LEDs. Examples of LEDs include, but are not limited to, LEDs that enable close spacing in a matrix lighting device. According to an embodiment, the particular LED can be a 1.0 square millimeter (mm²) die with two contact pads. According to another embodiment, the particular LED can be a 0.5 mm² die with two contact pads. The LED array, for example, can include eighteen (18) LEDs arranged in at least two rows. These LEDs may have a relatively large light emitting region with outer walls surrounded on at least one side by very thing reflectors, such as dichroic mirrors, which may enable very close spacing of the LEDs, such as described above, while still maintaining a crist contrast between neighboring LEDs. In some embodiments, the reflectors may only be placed in locations where the side wall is adjacent a side wall of a neighboring LED. For such LEDs, standard pick and place techniques may be difficult for the reasons described above, particularly as the close spacing makes any movement of the LEDs problematic for their functionality.

According to one or more embodiments, the solder mask layer of the PCB design may include at least one solder mask opening per LED of the LED array. The solder mask openings can be arranged in a grid to support the LED array. The solder mask layer, for example, can include eighteen (18) positions for the eighteen (18) LEDs of the LED array, where each position has at least one solder mask opening. Note that each position can be identified by the PCB design using a grid of X, Y coordinates. Further, each solder mask opening of the PCB design may be sized and shaped to directly accommodate contact pads of a corresponding LED that will be placed at that location on the die architecture. More particularly, a geometry of each solder mask opening may be designed to match a geometry of a back of a particular LED that will be picked and placed onto that solder mask opening.

According to one or more embodiments, a position on the die architecture can include at least one solder mask opening, such as a hybrid footprint or two (2) solder mask openings. Each solder mask opening may be configured to receive a volume of material for the solder to guarantee a solder BLT.

As shown by schematic 120 in FIG. 1, a solder mask layer 121 includes an opening 123. The opening 123 is a hybrid footprint. The hybrid footprint may include an envelope or a perimeter that matches a combined perimeter of the contact pads. For instance, the area of the hybrid footprint may match a total area of corresponding contact pads and spacing therebetween with +/−10 μm tolerances. The schematic 120 may accommodate an LED of a smaller dimension (e.g., 0.5 mm² die), where the contact pads are two close together to enable machining of separate openings. In an embodiment, the solder mask layer includes a grid of openings 123, each of which may correspond to a single LED.

Also, as shown by schematic 130 in FIG. 1, a solder mask layer 131 includes two (2) solder mask openings 133 and 135 (i.e., first and second openings). The dimensions of each solder mask opening 133 and 135 may match an area of each corresponding contact pad of a corresponding LED in a 1:1 aspect ratio with +/−10 μm tolerances. That is, a size of each solder mask opening 133 and 135 may be 1:1 to a contact pad on the LED, even if the contact pads are different sizes. The schematic 120 may accommodate an LED of a larger dimension (e.g., 1.0 mm² die), where the contact pads are two close together to enable machining of separate openings. In an embodiment, the solder mask layer includes a grid of pairs, each of pair including the first and second openings that correspond to a single LED.

At block 140, the PCB design is fed to the electronics manufacturing equipment for printing of a corresponding a die architecture. For instance, the die architecture may be manufactured according to rules of the PCB design, i.e., the die architecture is printed according to the PCB design having the solder BLT that enables self-aligning LEDs (i.e., controls movement of the LEDs). Printing the die architecture may include printing elements for supporting an LED array on a PCB. The elements include, but are not limited to, PCB solder pads (e.g., wiring layer that include electrical traces), solders with a BLT, solder masks, and LED solder pads. Printing the die architecture may further include depositing a volume of the solder in each solder mask opening to guarantee a solder BLT for a corresponding LED to self-align during the reflow process. According to one or more embodiments, dimensions of the BLT may be in a range of 20 μm to 40 μm. For example, the BLT may be 30 μm with a tolerance of +/−15 μm, such that a volume of the solder may be determined and printed onto the PCB accordingly.

At block 150, LEDs are picked and placed on the solders of the die architecture. The LEDs may be picked and placed in corresponding X, Y coordinates on the die architecture to form an LED array. The LED array can be a one by two array, a one by three array, a one by four array, etc. The LED array can be a two by two array, a two by three array, a two by four array, etc. By way of example, each LED of the LED array upon placement may be considered to be in a placement position (also referred to as an original position).

At block 160, a reflow process is implemented. Generally, the reflow process includes passing the die architecture with the LED array placed thereon through an oven to melt (i.e., reflow) the solder. After the oven, the die architecture with the LED array placed thereon may undergo a cooling stage where the solder may set (i.e., from liquid state to solid state), sealing the LEDs to the die architecture.

According to one or more embodiments, a self-alignment effect takes place during the reflow process where the solder is in a molten/liquid state. That is, the molten solder creates surface tension forces that pull the LED from the placement position into an intended position (also referred to as optimal or final position) via LED solder pads (contact pads) that are wetted by the molten solder. Thus, because the method 100 provided the PCB design and the solder BLT, the method 100 activity leverages forces of the solder meld to enable the LEDs to find an end result that is aligned or achieves a high placement accuracy, such as a placement accuracy h that is less than or equal to 50 μm spacing gap between the LEDs.

At block 170, a PCB with an LED array, where each LED has the high placement accuracy, is outputted (i.e., the one or more light-emitting diodes self-aligned on the die architecture). The PCB with the LED array can be considered a matrix lighting device, which can be further incorporated into automotive headlight applications and other lighting applications. That is, by enabling the self-aligning LEDs, the method 100 provides the LED array with the high placement accuracy on the PCB board. The PCB with the LED array suitable for a variety of lighting applications, such as automotive headlight applications. An example of the PCB with the LED array may be provided via a cross-sectional view 180. The cross-sectional view 180 includes an LED 181 (i.e., an LED body), an LED solder pad 182, a solder mask 183, a solder 185 with a BLT 186, a PCB solder pad (e.g., a wiring layer that includes electrical traces), and a PCB 189 (e.g., ceramic layer). According to one or more embodiments, the BLT 186 includes dimensions of 30 μm with a tolerance of +/−15 μm. According to one or more embodiments, the PCB soldering pad 188 has a 1:1 length to width ratio, with traces being isolated by the solder mask 183.

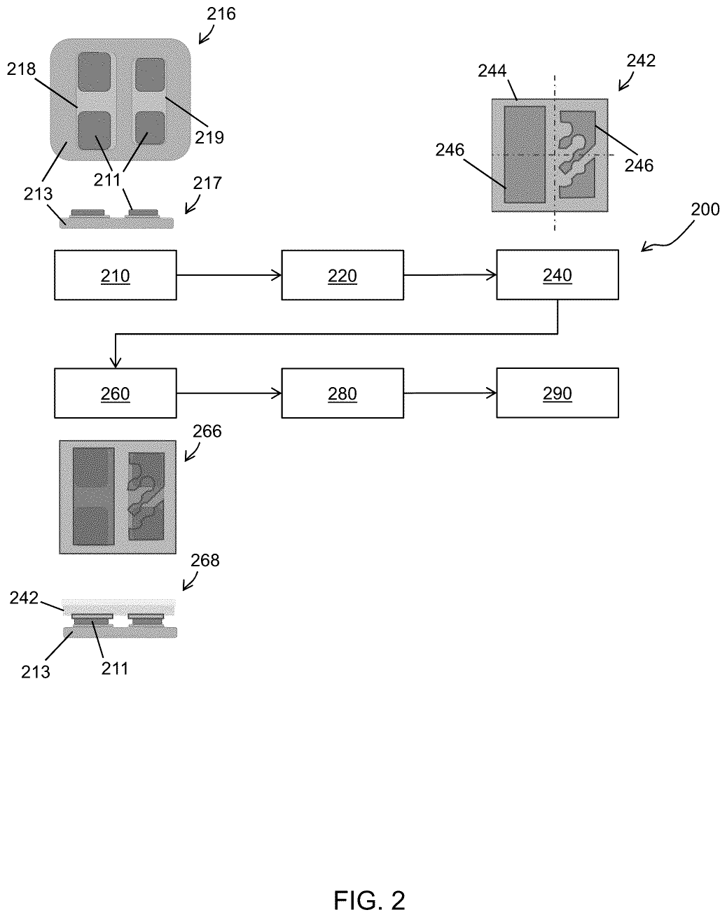

FIG. 2 shows an exemplary process flow 200 for enabling self-aligning LEDs according to one or more embodiments. The exemplary process flow 200 may be implemented by electronics manufacturing equipment as described herein.

At block 210, a screen printing of a PCB is implemented. More particularly, a solder paste 211 may be printed on substrate 213 as shown in a substrate top view 216 and a substrate side view 217. According to one or more embodiments, two deposits of solder paste 211 can be printed in each solder mask opening 218 and 219. At block 220, paste height measurements may be taken. For instance, serial peripheral interface (SPI) may be used to measure the height of the soldier paste. The height measurements may be utilized to confirm the BLT is within set toleration limits as described herein.

At block 240, an LED is centered over the PCB. According to one or more embodiments, an LED 242 is optically centered over the solder paste 211 using a package outline 244. Note that the LED 242 may include a rectangular silhouette 245 of a first solder pad and an irregular silhouette 246 of a second solder pad. The optical centering of the LED enables a placement location of the LED to be at or near an intended placement. At block 260, the LED 242 is mounted on top of the solder paste 211 printed on the substrate 213, as shown in a mounted top view 266 and a mounted side view 268. Note that the solder mask opening 218 has a 1:1 aspect ratio to the first solder pad (i.e., shown by the rectangular silhouette 245) and that the solder mask opening 219 has a 1:1 aspect ratio to the second solder pad (i.e., shown by the irregular silhouette 246).

At block 280, a reflow process or soldering is performed. The reflow process or soldering may include melting the solder to form a solder joint between the LED 242 and the substrate 213. As the optical centering of the LED enables the placement location of the LED to be at or near the intended placement, the surface tension forces cause the LED to remain at or near the intended placement. At block 290, the LED placement is measured to confirm self-aligning. According to one or more embodiments, an X-ray solder voiding measurement may be taken of the LED.

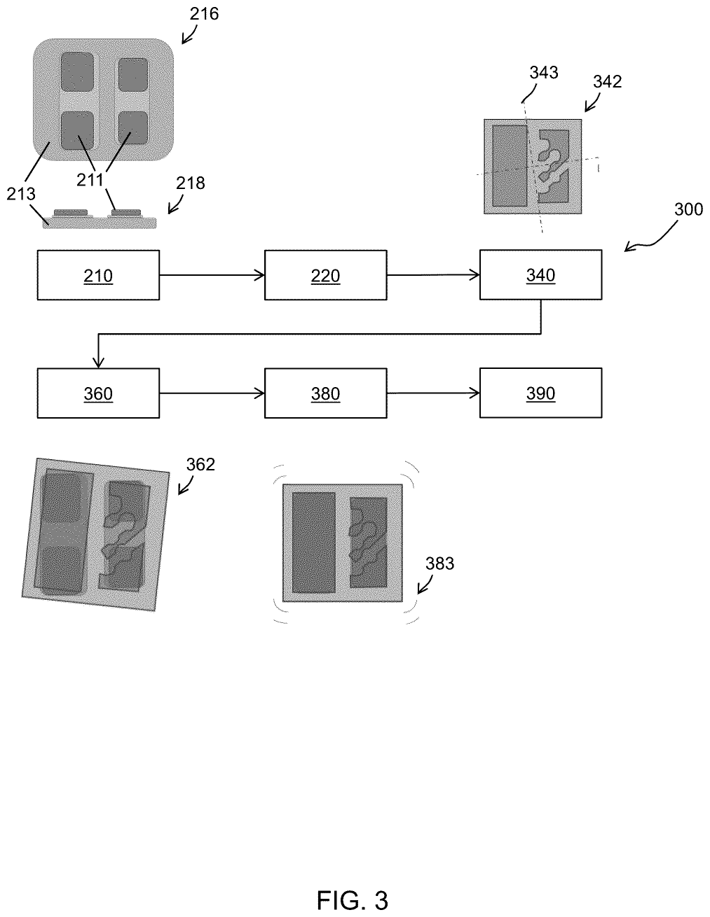

FIG. 3 shows an exemplary process flow 300 for enabling self-aligning LEDs according to one or more embodiments. The exemplary process flow 300 may be implemented by electronics manufacturing equipment as described herein. Elements and items of FIG. 3 that are similar to FIG. 2 reuse the same numbering for brevity and consistency.

At block 210 of FIG. 3, a screen printing is implemented. More particularly, a solder paste 211 may be printed on substrate 213 as shown in a substrate top view 216 and a substrate side view 217 of FIG. 3. At block 220, paste height measurements are taken. For instance, serial peripheral interface (SPI) may be used to measure the height of the soldier paste. The height measurements may be utilized to confirm the BLT is within set toleration limits as described herein.

At block 340, an LED 342 is centered over the PCB. In some cases, an error 343 can occur in centering. Thus, at block 360, the LED 342 is mounted on top of the solder paste 211 printed on the substrate 213 with the error 343 (the mounted LED has a minor misalignment), as shown in a mounted top view 362.

At block 380, a reflow process or soldering is performed. The reflow process or soldering may include melting the solder to form solder joint between the LED 342 and the substrate 213. As the solder is melted during the reflow process, a pullback effect 383 may occur (due to surface tension) that pulls the LED 342 back to an intended placement. At block 290, the LED placement is measured to confirm self-aligning. According to one or more embodiments, an X-ray solder voiding measurement may be taken of the LED.

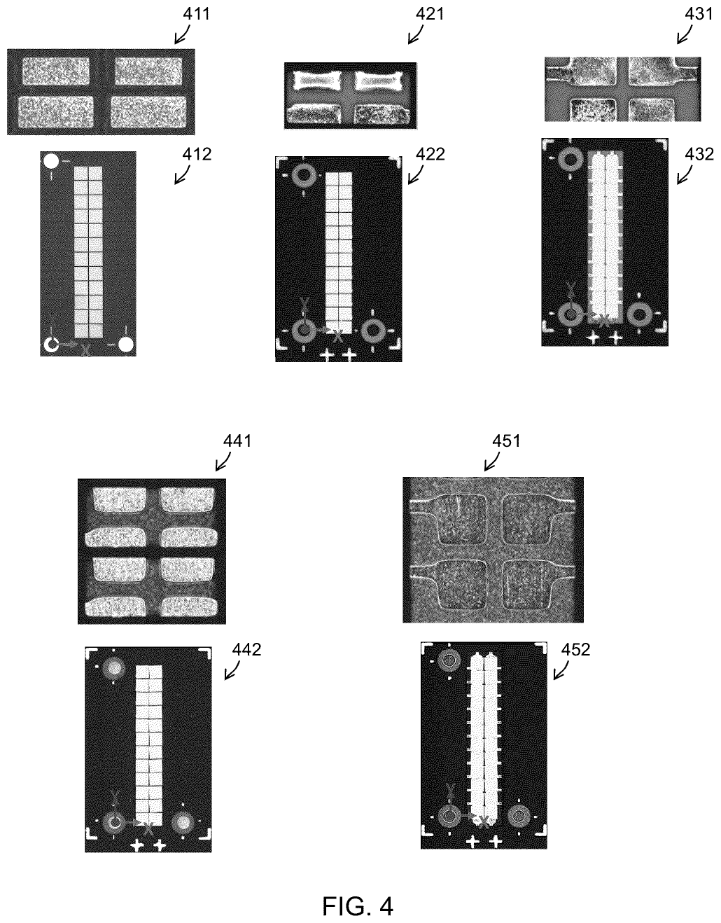

FIG. 4 shows a set of comparative examples of solder footprints and LED arrays according one or more embodiments. The set of comparative examples of solder footprints and LED arrangements include an “S” PCB 411, an LED array 412, a “K” RevA0 PCB 421, an LED array 422, a “K” RevB0 PCB 431, an LED array 432, a “R” RevA0 PCB 441, an LED array 442, a “R” RevB0 PCB 451, and an LED array 452. The “S” PCB 411 demonstrates dimensions of solder mask and solders (e.g., a volume of the solders determined to achieve a BLT in a range of 20 μm to 40 μm) that enable self-alignment of the LEDs of the LED array 412. By contrast, the solders of the “K” RevA0 PCB 421, the “K” RevB0 PCB 431, the “R” RevA0 PCB 441, and the “R” RevB0 PCB 451 do not include such dimensions and, thus, may not provide the self-alignment for the LED arrays 422, 432, 442, and 452.

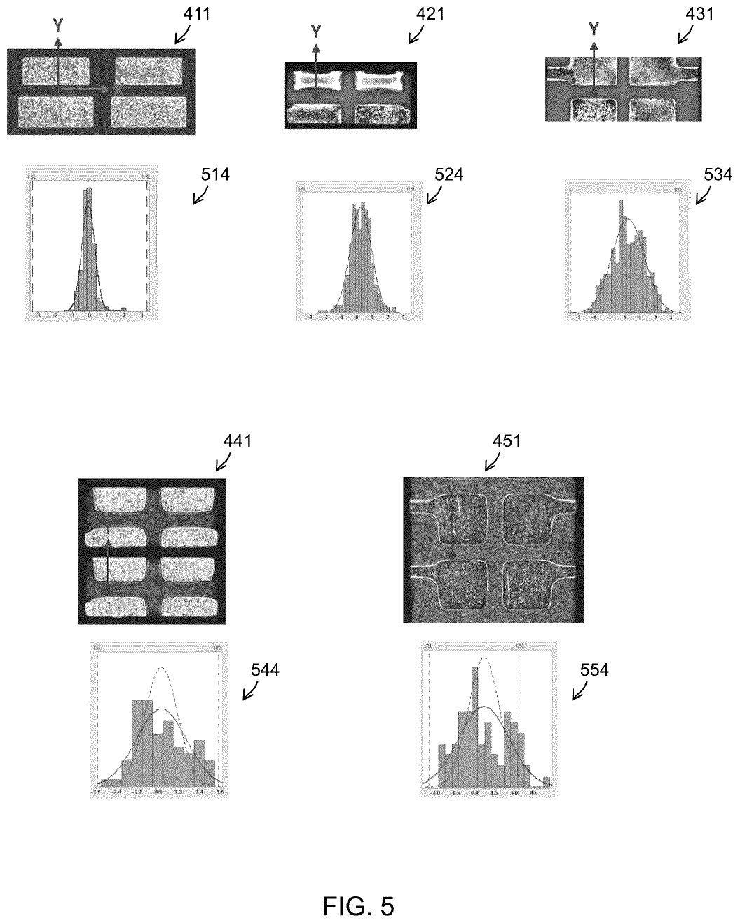

FIG. 5 shows a set of comparative graphical examples according one or more embodiments. Elements and items of FIG. 5 that are similar to FIG. 4 reuse the same numbering for brevity and consistency. The set of comparative graphical examples includes graphs 514, 524, 534, 544, and 554 that corresponding match the comparative solder footprints examples of the “S” PCB 411, the “K” RevA0 PCB 421, the “K” RevB0 PCB 431, the “R” RevA0 PCB 441, and the “R” RevB0 PCB 451. The graph 514 shows a range of −1.2′ to 2.1′ for the “S” PCB 411. The graph 524 shows a range of −2.4′ to 2.4′ for the “K” RevA0 PCB 421. The graph 534 shows a range of −2.5′ to 3.1′ for the “K” RevB0 PCB 431. The graph 544 shows a range of −3.5′ to 3.5′ for the “R” RevA0 PCB 441. The graph 554 shows a range of −3.0′ to 4.2′ for the “R” RevB0 PCB 451.

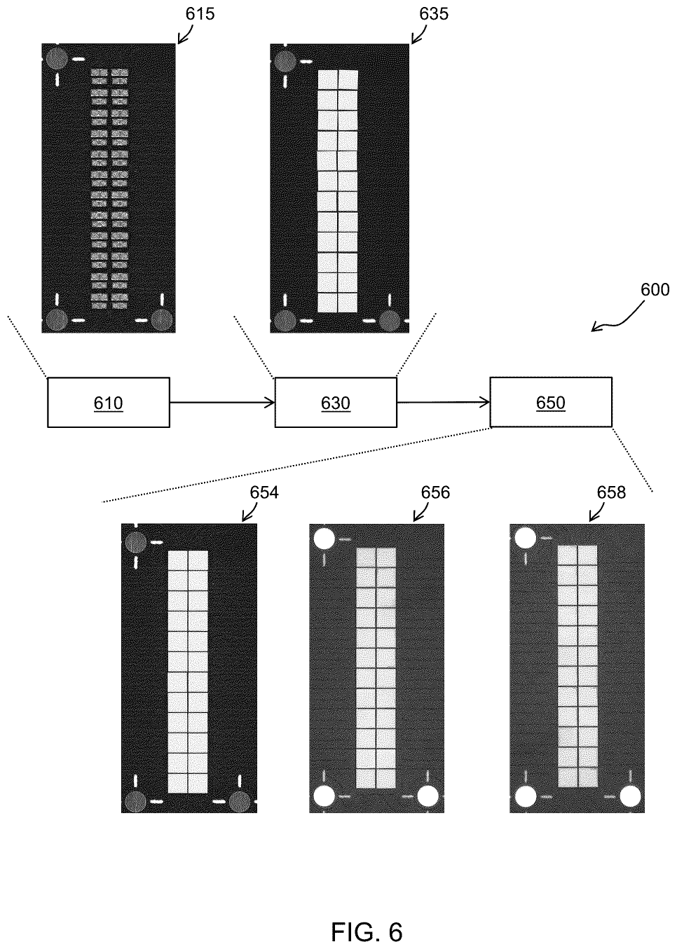

FIG. 6 shows a method 600 for enabling self-aligning LEDs according to one or more embodiments. The method 600 may be implemented by electronics manufacturing equipment as described herein. The method 600 is accompanied by example schematics showing a soldering process.

The method 600 may begin at block 610, where the PCB design is printed. The PCB design may be printed in accordance with one or more tolerances, such as a +/−50 μm tolerance discussed herein. According to one or more embodiments, the PCB design may include a +/−10 μm tolerance. The PCB design may be printed in accordance with a determined solder volume. According to one or more embodiments, the solder volume is calculated to provide the BLT along a range of 20 μm to 40 μm. For example, the BLT may be 30 μm with a tolerance of +/−15 μm. The PCB design may be printed in accordance with a BLT that is as great as 60 μm with a reduced placement accuracy. A printed PCB schematic 615 is shown with a two by twelve solder footprints.

At block 630, the LEDs are placed. Each LED upon placement may be considered to be in an original position, as shown by a pre-reflow schematic 635.

At block 650, the reflow process is implemented. The reflow process may trigger/enable the self-alignment process of the LEDs, where the LEDs may move or “swim” into intended positions. That is, each LED may move from the original position to an intended position during the reflow process, as shown by post reflow schematics 654, 656, and 658. The placement accuracies of +/−35 μm are achievable for a six (6) second cooling process (when the PCB undergoes a cooling stage and the solder transforms from liquid state to solid state),

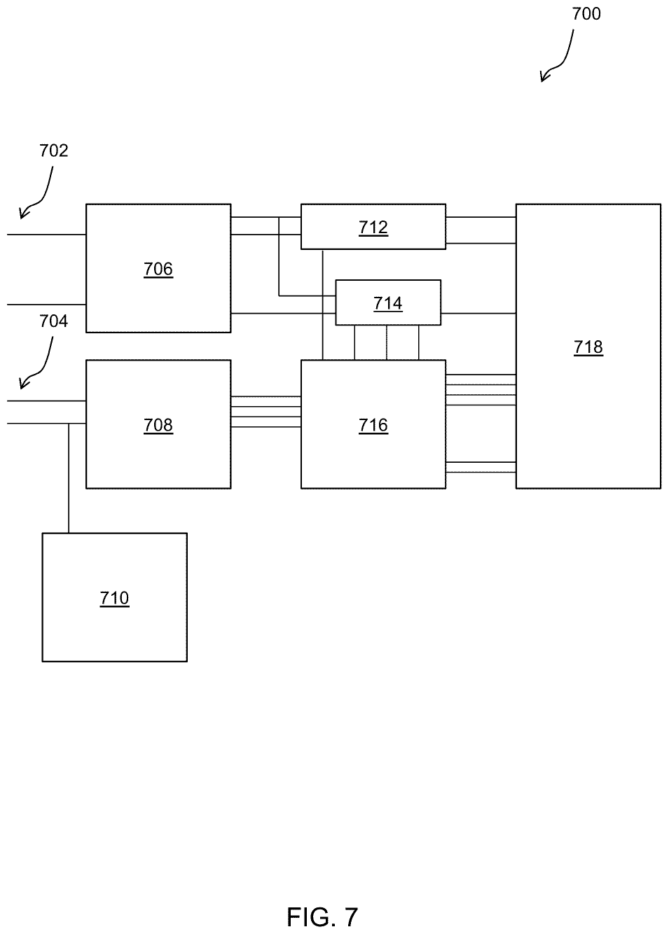

FIG. 7 is a diagram of an example vehicle headlamp system 700 that may incorporate one or more of the embodiments and examples described herein. The example vehicle headlamp system 700 illustrated in FIG. 7 includes power lines 702, a data bus 704, an input filter and protection module 706, a bus transceiver 708, a sensor module 710, an LED direct current to direct current (DC/DC) module 712, a logic low-dropout (LDO) module 714, a micro-controller 716 and an active head lamp 718.

The power lines 702 may have inputs that receive power from a vehicle, and the data bus 704 may have inputs/outputs over which data may be exchanged between the vehicle and the vehicle headlamp system 700. For example, the vehicle headlamp system 700 may receive instructions from other locations in the vehicle, such as instructions to turn on turn signaling or turn on headlamps, and may send feedback to other locations in the vehicle if desired. The sensor module 710 may be communicatively coupled to the data bus 704 and may provide additional data to the vehicle headlamp system 700 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 700. In FIG. 7, the headlamp controller may be a micro-controller, such as micro-controller (μc) 716. The micro-controller 716 may be communicatively coupled to the data bus 704.

The input filter and protection module 706 may be electrically coupled to the power lines 702 and may, for example, support various filters to reduce conducted emissions and provide power immunity. Additionally, the input filter and protection module 706 may provide electrostatic discharge (ESD) protection, load-dump protection, alternator field decay protection, and/or reverse polarity protection.

The LED DC/DC module 712 may be coupled between the input filter and protection module 106 and the active headlamp 718 to receive filtered power and provide a drive current to power LEDs in the LED array in the active headlamp 718. The LED DC/DC module 712 may have an input voltage between 7 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 714 may be coupled to the input filter and protection module 706 to receive the filtered power. The logic LDO module 714 may also be coupled to the micro-controller 716 and the active headlamp 718 to provide power to the micro-controller 716 and/or electronics in the active headlamp 718, such as CMOS logic.

The bus transceiver 708 may have, for example, a universal asynchronous receiver transmitter (UART) or SPI interface and may be coupled to the micro-controller 716. The micro-controller 716 may translate vehicle input based on, or including, data from the sensor module 710. The translated vehicle input may include a video signal that is transferrable to an image buffer in the active headlamp 718. In addition, the micro-controller 716 may load default image frames and test for open/short pixels during startup. In embodiments, an SPI interface may load an image buffer in CMOS. Image frames may be full frame, differential or partial frames. Other features of micro-controller 716 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

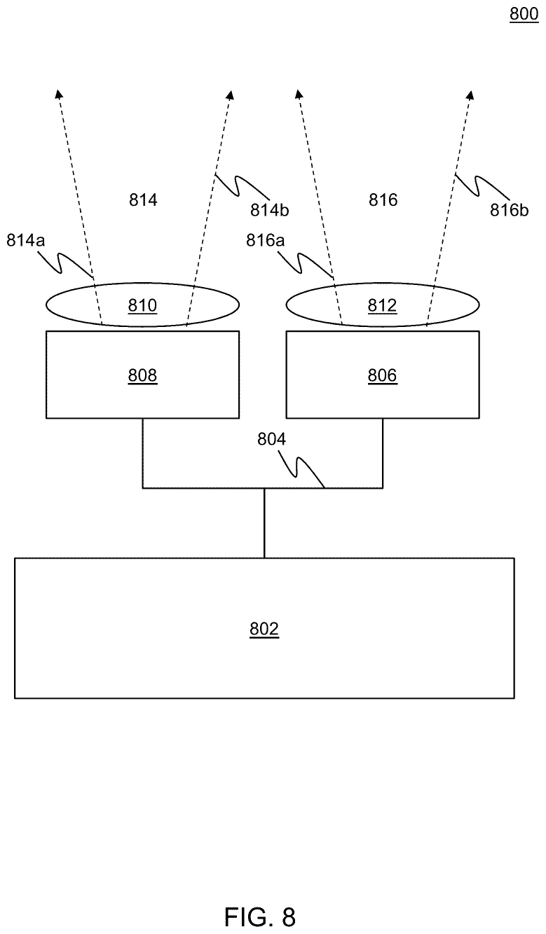

FIG. 8 is a diagram of another example vehicle headlamp system 800. The example vehicle headlamp system 800 illustrated in FIG. 8 includes an application platform 802, two LED lighting systems 806 and 808, and secondary optics 810 and 812.

The LED lighting system 808 may emit light beams 814 (shown between arrows 814a and 814b in FIG. 8). The LED lighting system 806 may emit light beams 816 (shown between arrows 816a and 816b in FIG. 8). In the embodiment shown in FIG. 8, a secondary optic 810 is adjacent the LED lighting system 808, and the light emitted from the LED lighting system 808 passes through the secondary optic 810. Similarly, a secondary optic 812 is adjacent the LED lighting system 806, and the light emitted from the LED lighting system 806 passes through the secondary optic 812. In alternative embodiments, no secondary optics 810/812 are provided in the vehicle headlamp system.

Where included, the secondary optics 810/812 may be or include one or more light guides. The one or more light guides may be edge lit or may have an interior opening that defines an interior edge of the light guide. LED lighting systems 808 and 806 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 808 and 806 in a desired manner, such as, for example, with a gradient, a chamfered distribution, a narrow distribution, a wide distribution, or an angular distribution.

The application platform 802 may provide power and/or data to the LED lighting systems 806 and/or 808 via lines 804, which may include one or more or a portion of the power lines 702 and the data bus 704 of FIG. 7. One or more sensors (which may be the sensors in the vehicle headlamp system 800 or other additional sensors) may be internal or external to the housing of the application platform 802. Alternatively, or in addition, as shown in the example vehicle headlamp system 700 of FIG. 7, each LED lighting system 808 and 806 may include its own sensor module, connectivity and control module, power module, and/or LED array.

In embodiments, the vehicle headlamp system 800 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 806 and 808 may be sensors (e.g., similar to sensors in the sensor module 710 of FIG. 7) that identify portions of a scene (e.g., roadway or pedestrian crossing) that require illumination.

According to one or more embodiments, a method for enabling self-aligning light-emitting diodes. The method includes printing a die architecture comprising one or more solders having a bond line thickness according to a printed circuit board design. The method includes placing one or more light-emitting diodes in corresponding placement positions onto the one or more solders. The method includes implementing a reflow process that includes a self-alignment effect for the one or more light-emitting diodes. The self-alignment effect includes creating surface tension forces while the one or more solders are molten that pull or hold the one or more light-emitting diodes to or at final positions.

According to one or more embodiments or any of the methods herein, a dimension of the bond line thickness can include a value in a range of 20 μm to 40 μm.

According to one or more embodiments or any of the methods herein, the value can be 30 μm with a tolerance of +/−15 μm.

According to one or more embodiments or any of the methods herein, a volume of the one or more solders printed onto a printed circuit board can be determined based on to the bond line thickness.

According to one or more embodiments or any of the methods herein, the one or more light-emitting diodes can be placed in an light-emitting diode array.

According to one or more embodiments or any of the methods herein, the reflow process can include utilizing an oven to melt the one or more solders and setting the one or more solders from a liquid state to a solid state.

According to one or more embodiments or any of the methods herein, the self-alignment effect can provide a placement accuracy that is less than or equal to 50 μm spacing gap between the one or more light-emitting diodes.

According to one or more embodiments or any of the methods herein, the one or more light-emitting diodes can be pulled by the surface tension forces from the corresponding placement positions to the final positions.

According to one or more embodiments or any of the methods herein, solder pads of the one or more light-emitting diodes can be wetted while the one or more solders are molten to secure the one or more light-emitting diodes to the one or more solders.

According to one or more embodiments or any of the methods herein, the one or more light-emitting diodes can be optically aligned on the one or more solders after placement and before the reflow process.

According to one or more embodiments or any of the methods herein, the method can include generating the printed circuit board design including the bond line thickness for the one or more solders that enable the self-alignment effect for the one or more light-emitting diodes.

According to one or more embodiments or any of the methods herein, the die architecture can include at least one solder mask opening for receiving the one or more solders.

According to one or more embodiments or any of the methods herein, the at least one solder mask opening can include a hybrid footprint.

According to one or more embodiments or any of the methods herein, the hybrid footprint can include a perimeter that matches a combined perimeter of two contact pads of a corresponding light-emitting diode.

According to one or more embodiments or any of the methods herein, the corresponding light-emitting diode can include a 0.5 mm² die.

According to one or more embodiments or any of the methods herein, the at least one solder mask opening can include first and second solder mask openings.

According to one or more embodiments or any of the methods herein, the first and second solder mask openings can match, by 1:1 aspect ratios with +/−10 μm tolerances, first and second contact pads of a corresponding light-emitting diode.

According to one or more embodiments or any of the methods herein, the corresponding light-emitting diode can include a 1.0 mm² die.

According to one or more embodiments or any of the methods herein, a geometry of each solder mask opening of the die architecture can match a geometry of a back of a corresponding light-emitting diode of the one or more light-emitting diodes.

According to one or more embodiments or any of the methods herein, the method can include outputting a matrix lighting device comprising the one or more light-emitting diodes self-aligned on the die architecture.

According to one or more embodiments, a die architecture is provided. The die architecture includes a printed circuit board and a wiring layer on the printed circuit board. The wiring layer includes electrical traces. The die architecture includes a solder mask layer on the wiring layer. The solder mask layer includes at least one solder mask opening. The die architecture includes a solder in the at least one solder mask opening and a light-emitting diode sealed to the solder. The solder includes a bond line thickness enabling a self-alignment effect by the light-emitting diode.

According to one or more embodiments or any of the die architecture herein, a geometry of the at least one solder mask opening can match a geometry of a back of the light-emitting diode.

According to one or more embodiments or any of the die architecture herein, a dimension of the bond line thickness can include a value in a range of 20 μm to 40 μm.

According to one or more embodiments or any of the die architecture herein, the value can be 30 μm with a tolerance of +/−15 μm.

According to one or more embodiments or any of the die architecture herein, the at least one solder mask opening can be one of a grid of openings corresponding in a light-emitting diode array.

According to one or more embodiments or any of the die architecture herein, the die architecture can be included in a matrix lighting device.

According to one or more embodiments or any of the die architecture herein, the at least one solder mask opening can include a hybrid footprint.

According to one or more embodiments or any of the die architecture herein, the hybrid footprint can include a perimeter that matches a combined perimeter of two contact pads of the light-emitting diode.

According to one or more embodiments or any of the die architecture herein, the light-emitting diode can include a 0.5 mm² die.

According to one or more embodiments or any of the die architecture herein, the at least one solder mask opening can include first and second solder mask openings.

According to one or more embodiments or any of the die architecture herein, the first and second solder mask openings can match, by 1:1 aspect ratios with +/−10 μm tolerances, first and second contact pads of the light-emitting diode.

According to one or more embodiments or any of the die architecture herein, the light-emitting diode can include a 1.0 mm² die.

According to one or more embodiments or any of the die architecture herein, the self-alignment effect can include pulling the light-emitting diode by surface tension forces from a placement position to a final position.

According to one or more embodiments or any of the die architecture herein, the light-emitting diode can be one of a plurality of light-emitting diodes arranged in a light-emitting diode array.

According to one or more embodiments or any of the die architecture herein, the light-emitting diode array can include eighteen light-emitting diodes arranged in at least two rows.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

What is claimed is:

1. A method for enabling self-aligning light-emitting diodes, the method comprising:
printing a die architecture comprising one or more solders having a bond line thickness according to a printed circuit board design;
placing one or more light-emitting diodes in corresponding placement positions onto the one or more solders; and
implementing a reflow process that includes a self-alignment effect for the one or more light-emitting diodes, the self-alignment effect comprises creating surface tension forces while the one or more solders are molten that pull or hold the one or more light-emitting diodes to or at final positions.

2. The method of claim 1, wherein a dimension of the bond line thickness comprises a value in a range of 20 μm to 40 μm.

3. The method of claim 1, wherein a volume of the one or more solders printed onto a printed circuit board is determined based on to the bond line thickness.

4. The method of claim 1, wherein the one or more light-emitting diodes are placed in an light-emitting diode array.

5. The method of claim 1, wherein the reflow process comprises utilizing an oven to melt the one or more solders and setting the one or more solders from a liquid state to a solid state.

6. The method of claim 1, wherein the self-alignment effect provides a placement accuracy that is less than or equal to 50 μm spacing gap between the one or more light-emitting diodes.

7. The method of claim 1, wherein the one or more light-emitting diodes are pulled by the surface tension forces from the corresponding placement positions to the final positions.

8. The method of claim 1, wherein solder pads of the one or more light-emitting diodes are wetted while the one or more solders are molten to secure the one or more light-emitting diodes to the one or more solders.

9. The method of claim 1, wherein the one or more light-emitting diodes are optically aligned on the one or more solders after placement and before the reflow process.

10. The method of claim 1, further comprising:
generating the printed circuit board design comprising the bond line thickness for the one or more solders that enable the self-alignment effect for the one or more light-emitting diodes.

11. The method of claim 1, wherein the die architecture comprises at least one solder mask opening for receiving the one or more solders.

12. The method of claim 11, wherein the at least one solder mask opening comprises a hybrid footprint, and
wherein the hybrid footprint comprises a perimeter that matches a combined perimeter of two contact pads of a corresponding light-emitting diode.

13. The method of claim 11, wherein the at least one solder mask opening comprises first and second solder mask openings, and
wherein the first and second solder mask openings match, by 1:1 aspect ratios with +/−10 μm tolerances, first and second contact pads of a corresponding light-emitting diode.

14. The method of claim 1, wherein a geometry of each solder mask opening of the die architecture matches a geometry of a back of a corresponding light-emitting diode of the one or more light-emitting diodes.

15. The method of claim 1, further comprising:
outputting a matrix lighting device comprising the one or more light-emitting diodes self-aligned on the die architecture.

16. A die architecture comprising:
a printed circuit board;
a wiring layer on the printed circuit board, the wiring layer comprising electrical traces;
a solder mask layer on the wiring layer, the solder mask layer comprising at least one solder mask opening;
a solder in the at least one solder mask opening; and
a light-emitting diode sealed to the solder,
wherein the solder comprises a bond line thickness enabling a self-alignment effect by the light-emitting diode.

17. The die architecture of claim 16, wherein a geometry of the at least one solder mask opening matches a geometry of a back of the light-emitting diode.

18. The die architecture of claim 16, wherein the at least one solder mask opening is one of a grid of openings corresponding in a light-emitting diode array.

19. The die architecture of claim 16, wherein the die architecture is included in a matrix lighting device.

20. The die architecture of claim 16, wherein the at least one solder mask opening comprises a hybrid footprint or first and second solder mask openings.
